(19) United States
(12) Patent Application Publication
(10) Pub. No.: US 2025/0040265 A1
(43) Pub. Date: Jan. 30, 2025

(54) BROADBAND SILICON SENSOR

(71) Applicant: SRI International, Menlo Park, CA (US)

(72) Inventors: John McCarten, Penfield, NY (US); Namwoong Paik, Lawrenceville, NJ (US)

(21) Appl. No.: 18/717,984

(22) PCT Filed: Nov. 17, 2022
(86) PCT No.: PCT/US2022/080066

§ 371 Date: Jun. 7, 2024

Related U.S. Application Data
(60) Provisional application No. 63/292,358, filed on Dec. 21, 2021.

(51) Int. Cl. H01L 27/146; H01L 31/101

(52) U.S. Cl. CPC H01L 27/14649; H01L 27/14683; H01L 31/1013

(57) ABSTRACT

In general, the disclosure describes sensor including an intermediate band layer including a plurality of dopant particles, wherein the intermediate band layer is configured to absorb a portion of incident electromagnetic radiation comprising a first range of wavelengths greater than 1100 nm and form optically induced minority carriers. The sensor also includes a photo-sensitive silicon substrate configured to detect the electromagnetic radiation comprising a second range of wavelengths less than or equal to 1100 nm.

This application claims the benefit of U.S. Provisional Patent Application 63/292,358, filed Dec. 21, 2021, the entire content of which is incorporated herein by reference.

### TECHNICAL FIELD

This disclosure generally relates to imaging devices.

### BACKGROUND

An image sensor may be a semiconductor device for converting an optical image into electric signals. The image sensor may include a photo-sensitive silicon element capable of detecting light in the ultraviolet (UV), visible, and/or near infrared (NIR, e.g., up to about 1100 nanometers (nm)) wavelength ranges. Image sensors configured to detect light having wavelengths greater than 1100 nm, e.g., short wave infrared (SWIR), mid-wave infrared (MWIR), and/or long wave infrared (LWIR) are typically expensive due to the need to use materials and/or techniques capable of detecting the lower energy light, e.g., indium gallium arsenide (InGaAs), mercury cadmium telluride (HgCdTe), germanium, lead sulfide (PbS), indium antimonide (InSb), indium arsenide (InAs), lead selenide, lithium tantalate (LiTaO3), platinum silicide (PtSi), microbolometers, photomultiplier tubes, and the like.

### SUMMARY

In general, the disclosure describes a sensor having an intermediate band layer and readout structure that increases the absorption and sensitivity of a silicon sensor for electromagnetic radiation comprising frequencies having energies less than the energy gap (also referred to as the band gap) between valence and conduction bands of the silicon sensor, e.g., light having wavelengths greater than 1100 nm. In some examples, the intermediate band layer includes a plurality of dopant particles configured to absorb photons having energies lower than the band gap of the silicon sensor to form optically induced minority carriers, e.g., electrons or holes. The intermediate band layer may be formed in a photo-sensitive silicon substrate adjacent to an n-p junction formed in the photo-sensitive silicon substrate, and the n-p junction may be configured to convert a carrier optically induced in the intermediate band to a carrier in the conduction band or the valence band, e.g., to convert the carrier to an electron in the conduction band or a hole in the valence band depending on how the n-p junction is biased. In this way, the sensor may be used to detect both shorter wavelength light within to normal responsivity range of a silicon sensor, e.g., light having wavelengths less than or equal to about 1100 nm including UV, visible, and NIR light, as well as longer wavelength light (e.g., IR light) having wavelengths greater than 1100 nm that the photo-sensitive silicon substrate would not otherwise be capable of detecting.

Accordingly, the techniques may provide one or more technical advantages that realize at least one practical application. For example, the techniques may improve the NIR quantum efficiency for increased night vision capability, e.g., for light having a wavelength range between 800 nm and 1050 nm, of sensors utilizing silicon as a photo-sensitive substrate, e.g., complementary metal-oxide semiconductor (CMOS) or charge coupled device (CCD) sensors. The techniques may also extend the wavelength range sensitivity of a silicon-based sensor, e.g., to the SWIR, MWIR, LWIR, or other electromagnetic wavelength ranges. For example, the techniques may extend the wavelength responsivity of relatively lower cost silicon-based sensors such as CMOS, CCD, and the like, to sense 1550 nm light used as eye safe laser light, light detection and ranging (LIDAR), laser designator light, or the like. In other words, the techniques may provide a lower cost, silicon-based sensor configured to sense electromagnetic radiation wavelength ranges not otherwise detectable using a photo-sensitive silicon substrate.

In one example, this disclosure describes a sensor including: an intermediate band layer comprising a plurality of dopant particles, wherein the intermediate band layer is configured to absorb a portion of incident electromagnetic radiation comprising a first range of wavelengths greater than 1100 nm and form optically induced minority carriers; and a photo-sensitive silicon substrate configured to detect the electromagnetic radiation comprising a second range of wavelengths less than or equal to 1100 nm.

In another examples, this disclosure describes a method of forming a sensor, the method including: forming an intermediate band layer comprising a plurality of dopant particles on a surface of a photo-sensitive silicon substrate, wherein the intermediate band layer is configured to absorb a portion of incident electromagnetic radiation comprising a first range of wavelengths greater than 1100 nm and form optically induced minority carriers.

In another examples, this disclosure describes a method of detecting electromagnetic radiation, the method including: absorbing, by a silicon sensor comprising an intermediate band layer comprising a plurality of dopant particles, incident electromagnetic radiation comprising a first range of wavelengths greater than 1100 nm, wherein absorbing the incident electromagnetic radiation comprising a first range of wavelengths greater than 1100 nm forms optically induced minority carriers; and converting, via an n-p junction of the photo-sensitive silicon substrate, a minority carrier optically induced in the intermediate band layer to a carrier in a conduction band or a valence band of the silicon sensor.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1 is a cross-sectional block diagram illustrating an example sensor, in accordance with the techniques of the disclosure.

FIG. 2 is an expanded view of a portion of the cross-sectional block diagram of FIG. 1 illustrating an example intermediate band layer of an example sensor, in accordance with the techniques of the disclosure.

FIG. 3 is an expanded view of a portion of the cross-sectional block diagram of FIG. 1 illustrating another example intermediate band layer of another example sensor, in accordance with the techniques of the disclosure.

FIG. 4 is a cross-sectional block diagram illustrating another example sensor, in accordance with the techniques of the disclosure.

FIG. 5 is a cross-section top view of a pixel array including an plurality of sensors at a depth within the sensors including an intermediate band layer, in accordance with the techniques of the disclosure.

FIG. 6 is a cross-sectional block diagram illustrating another example sensor, in accordance with the techniques of the disclosure.

FIG. 7 is a cross-sectional block diagram illustrating another example sensor, in accordance with the techniques of the disclosure.

FIG. 8 is a cross-sectional block diagram illustrating another example sensor, in accordance with the techniques of the disclosure.

FIG. 9 is a cross-sectional block diagram illustrating another example sensor, in accordance with the techniques of the disclosure.

FIG. 10 is a cross-sectional block diagram illustrating another example sensor, in accordance with the techniques of the disclosure.

FIG. 11 is a schematic diagram of a readout circuit that can be used to read out signal from an example sensor, in accordance with the techniques of the disclosure.

FIG. 12 is a flow diagram of an example method of forming a sensor, in accordance with the techniques of the disclosure.

FIG. 13 is a flow diagram of an example method of detecting electromagnetic radiation, in accordance with the techniques of the disclosure.

Like reference characters refer to like elements throughout the figures and description.

### DETAILED DESCRIPTION

Detecting infrared light, e.g., short-wave infrared (SWIR), mid-wave infrared (MWIR), and long-wave infrared (LWIR) is typically done with materials and/or techniques capable of detecting the lower energy light, e.g., indium gallium arsenide (InGaAs) or other sensors, and is typically outside of the wavelength range of silicon-based sensors. For example, the long wavelength cut-off of silicon-based sensors is typically about 1100 nanometers (nm), where the absorption of silicon cuts off. Due to the cost of the materials and processing, such infrared light sensors may cost many times more than silicon-based sensors. As used herein, ultraviolet (UV) light includes electromagnetic radiation having wavelengths from the tens of nm to the low range of the sensitivity of the human eye, e.g., from about 10 nm (deep UV) to about 380 nm. Visible light wavelengths range from about 380 nm to 700 nm, near infrared (NIR) wavelengths range from about 700 nm to 1100 nm, SWIR wavelengths range from about 1100 nm to 3000 nm (e.g., 1.1 μm to 3 um), MWIR wavelengths range from about 3 μm to 5 μm, and LWIR ranges from about 5 μm to 14 um.

In accordance with the systems, devices, and techniques described here, a sensor comprises an intermediate band layer comprising a plurality of dopant particles, the intermediate band layer being configured to absorb a portion of incident electromagnetic radiation comprising a first range of wavelengths greater than 1100 nm and form optically induced minority carriers. The intermediate band layer may be applied to the top or back side of a silicon-based sensor and/or imaging sensor array, such as a CMOS imager, CCD imager, or the like, and the silicon-based sensor may be configured to read out the optically induced minority carriers, thereby outputting a signal proportional to light in the first range of wavelength that the silicon-based sensor would not otherwise be sensitive to. For example, the intermediate band layer may be formed in a photo-sensitive silicon substrate adjacent to an n-p junction with the photo-sensitive silicon substrate, the n-p junction being configured to convert an optically induced carrier in the intermediate band to a carrier, e.g., an electron or a hole, in the conduction or valence band of the sensor for readout.

In some examples, the example sensors described here (e.g., sensors 100-500, 1500, 1600 described below) may be useful for extending the responsivity of silicon-based sensors into the SWIR wavelength range, e.g., to sense relatively bright SWIR sources such as laser designators and fiber optic systems or the like or to measure beam distribution for eye safe lasers (e.g., when used in a sensor array). In other words, the example sensors described herein may extend the capabilities of silicon-based sensors to improve threat detection, identification of eye safe and non-eye safe laser designators, locating eye safe and non-eye safe laser designators in a scene (e.g., via overlay with an image of a scene showing the field of view of the sensor and/or sensor array), provide night vision while allowing a user to see/detect laser designators on a remote target as well as to locate a SWIR laser, e.g., if the user is being laser designated.

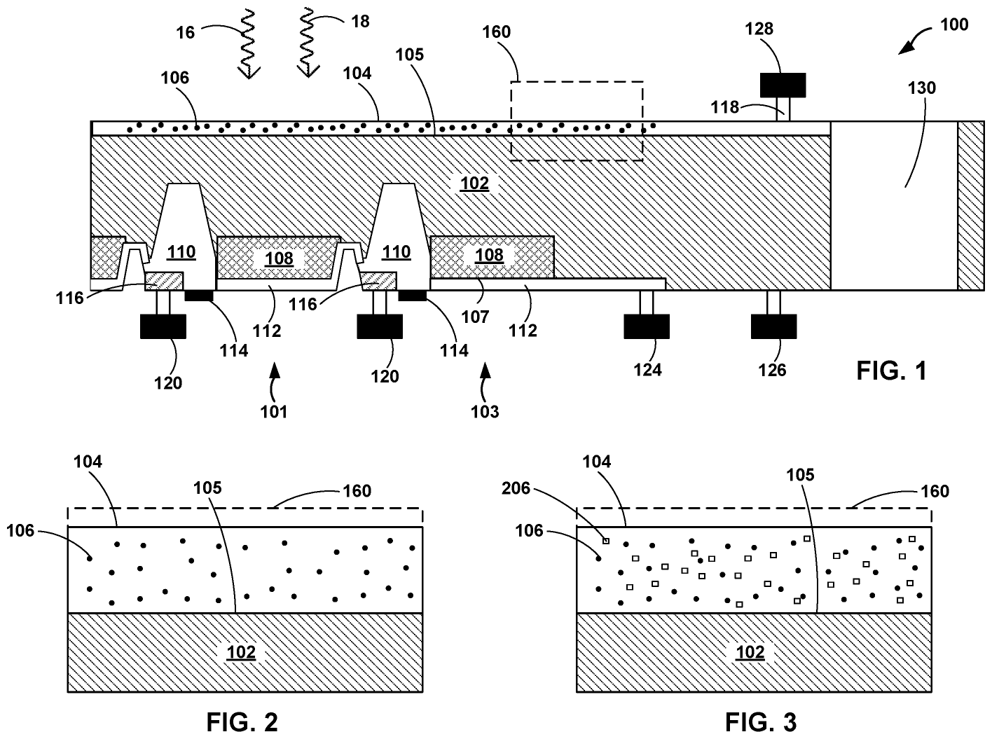

FIG. 1 is a cross-sectional block diagram illustrating an example sensing device 100, in accordance with the techniques of the disclosure. In the example shown, sensing device 100 comprises a plurality of backside illuminated sensors (alternatively referred to as “pixels” or “sensor pixels”) configured to collect holes of electron-hole pairs generated by the absorption of electromagnetic radiation and/or photons 16 (e.g., light 16) having a first range of wavelengths that is greater than 1100 nm and/or electromagnetic radiation and/or photons 18 (e.g., light 18) having a second range of wavelengths that is less than or equal to 1100 nm in a photodiode 108 for readout. In other examples, sensing device 100 may be constructed as a single sensor or pixel, or as a front side illuminated sensor. In other examples, sensing device 100 may be configured to collected electrons of electron-hole pairs generated by the absorption of photons in a photodiode for readout, e.g., by reversing (e.g., swapping) the p-type and n-type semiconductor layers and/or components as well as the relevant biases applied to those components relative to the description of FIG. 1 herein.

In the example shown, FIG. 1 illustrates two adjacent sensors 101 and 103 near to an edge (e.g., isolation trench 130) of an array of sensors of sensing device 100. In the example shown, sensing device 100 includes p-type silicon 102. The “front side” (e.g., semiconductor processing side) of p-type silicon includes n-wells 110, p-type photodiodes 108, p-channel transistors 116, gate contacts 114, and n-type pinning layer 112. For example, each of sensors 101 and 103 includes an n-well 110, a p-type photodiode 108, a p-channel transistor 116, a gate contact 114, and an n-type pinning layer 112.

Sensing device 100 and sensors 101 and 103 may be examples of back side illuminated (BSI) sensors, e.g., sensitive to light 16 and/or light 18 incident on the back side of sensing device 100, e.g., a surface of intermediate band layer 104. The designation of front and back sides of sensing device 100 herein refer to the front and back sides during semiconductor processing, unless otherwise specified. For sensing device 100 as a BSI, light 16 and light 18 is incident on a back side surface of sensing device 100, e.g., a surface of intermediate band layer 104 in the example shown. In other words, sensing device 100 is configured with intermediate band layer 104 on the back side of sensing device 100 and the readout transistors and photodiodes 108 are located on sensing device 100 on an opposite side of intermediate band layer 104 from a surface of intermediate band layer 104 on which light 16 and light 18 is incident.

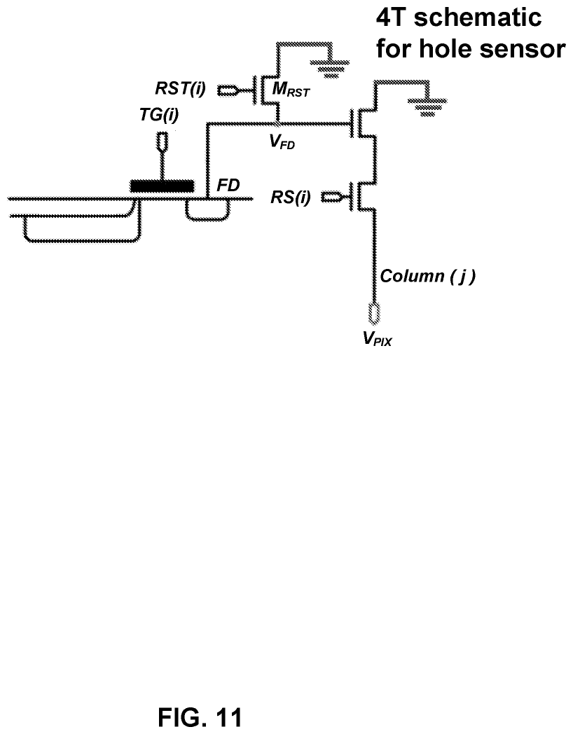

Sensors 101 and 103 are configured to collect photo-induced carriers. In the example shown, sensors 101 and 103 are configured to collect holes. Holes from photo-induced electron-hole pairs may be swept into photodiode 108 and electrodes may be swept out of a front side or back side bias. For example, sensing device 100 includes backside contact 128 electrically connected to intermediate band layer 104 (which may comprise an n-type semiconductor) by an electrical connection 118 (also referred to as a “via”, a trench, or the like) and front side bias contact 124 electrically connected to pinning layer 112 by an electrical connection (e.g., a via, trench, or the like). A positive bias voltage may be applied to one or both of contacts 124, 128 to sweep out photo-induced electrons. The photo-induced holes may then be read out by a readout circuit, e.g., readout circuit 1100 of FIG. 11 below. For example, sensors 101 and 103 may include a readout transistor comprising a FD contact 120 electrically connected to fully depleted (FD) p-type silicon 116 and gate contact 114, each of which are adjacent to and in electrical contact with n-well 110. Applying a current or voltage to gate contact 114 allows holes collected in photodiode 108 to be swept out through FD p-type silicon 116 and FD contact 120, which may be connected to a readout circuit, such as a four-transistor readout circuit. In some examples, FD contact 120 may be a collector or emitter of a readout transistor of sensors 101 and/or 103.

In the example shown, p-type silicon 102 is electrically connected to contact 126. In some examples, p-type silicon 102 may be connected to electrical ground via contact 126. In some examples, any or all of contacts 124, 126, and 128 may be located at one or more edges, boundaries, or the periphery of sensing device 100.

In the example shown, sensing device 100 and sensors 101 and 103 include n-type pinning layer 112. N-type pinning layer 112 may be configured to reduce a dark current of sensors 101 and 103, e.g., to reduce surface state dark current. For example, majority carriers may accumulate in the pinning region and reduce the dark current from these regions. In some examples, n-type pinning layer may be grounded, or a positive voltage bias may be applied to n-type pinning layer 112. For example, n-type pinning layer 112 may be electrically connected to front side bias contact 124, e.g., by a via, and front side bias contact may be connected to ground or a positive bias may be applied to front side bias contact 124 to apply a positive bias to n-type pinning layer 112.

In the example shown, sensing device 100 includes intermediate band layer 104. Intermediate band layer 104 comprises a plurality of dopant particles 106 and is configured to absorb a portion of incident electromagnetic radiation comprising wavelengths greater than 1100 nm and to form optical induced minority carriers, e.g., holes and/or electrons. For example, the plurality of dopants 106 may comprise one or more particles and/or particle types having a large optical capture cross-section and with defined energy states within the energy bandgap of the sensors 101 and 103, e.g., the energy bandgap of the photo-sensitive silicon substrate. For example, sensors 101 and 103 may comprise a photo-sensitive silicon substrate configured to detect electromagnetic radiation comprising wavelengths less than or equal to 1100 nm without intermediate band layer 104, and intermediate band layer 104 is configured to extend the range of detectable electromagnetic wavelengths to wavelengths greater than 1100 nm. In the example shown with sensing device 100 configured to collect holes, intermediate band layer 104 comprises an n-type layer including the plurality of dopant particles 106.

Intermediate band layer 104 may be a substantially “shallow” region adjacent to a surface of the back side of sensors 101 and 103. In some examples, the shallow region comprises less than 50% of the depth (e.g., thickness) of sensors 101 and 103 between the front and back sides of sensing device 100, or less than 10% of the depth of sensors 101 and 103 between the front and back sides, or less than 5% of depth of sensors 101 and 103 between the front and back sides. In some examples, the plurality of dopant particles 106 may be pre-placed in the shallow region, e.g., intermediate band layer 104, and then activated, or the plurality of dopant particles 106 may be placed in the intermediate band layer 104 and pre-activated and/or activated concurrently with placing the plurality of dopant particles 106 in the intermediate band layer 104, e.g., via gas phased pulsed laser, or by any suitable doping/activating technique.

Intermediate band layer 104 may include the plurality of dopant particles 106 dispersed substantially uniformly throughout the volume of intermediate band layer 104. Intermediate band layer 104 may include the plurality of dopant particles 106 in any suitable concentration and/or density. For example, intermediate band layer 104 may include the plurality of dopant particles 106 with at least a 0.1% density, at least a 1% density, at least a 10% density, at least a 50% density, at least a 90% density, at least a 99% density, or any suitable density.

In some examples, intermediate band layer 104 comprises an intermediate energy band level configured to collect minority carriers, e.g., holes or electrons, wherein a first energy gap between the intermediate energy band level and the conduction band or the valence band of the photo-sensitive silicon substrate is less than second energy gap between the conduction band and the valence band of the photo-sensitive silicon substrate. For example, a density of the plurality of dopant particles 106 in intermediate band layer 104 may be large enough to create and/or form at least one intermediate energy band level within the photo-sensitive silicon substrate energy bandgap, e.g., an intermediate energy band level for which a first energy gap between the intermediate energy band level and the conduction band or the valence band of the photo-sensitive silicon substrate is less than second energy gap between the conduction band and the valence band of the photo-sensitive silicon substrate. In some examples, the plurality of dopant particles 106 comprises at least one of a chalcogen, sulfur, selenium, tellurium, sulfur, titanium, germanium, hydrogen, or silicon.

In some examples, intermediate band layer 104 may be near and/or adjacent to an n-p junction 105. The n-p junction 105 may be configured to convert an optically induced carrier in intermediate band layer 104 to carrier in the valence band (or the conduction band), e.g., of the photo-sensitive silicon substrate. For example, the junction region between intermediate band layer 104 and p-type silicon 102 may form an electric field, such as a junction potential, configured to sweep holes out of intermediate band layer 104 and into photodiode 108. In some examples, intermediate band layer 104 is electrically connected to backside contact 128 and a reverse bias potential may be applied to intermediate band layer 104 to form an electric field substantially near n-p junction 105 by application of a voltage to backside contact 128. The electric field from one or both of the junction potential and reverse bias potential may be sufficient to cause a minority carrier (e.g., a hole) within intermediate band layer 104 to transition to the valence band or the conduction band. In other words, the junction potential and/or reverse bias potential may provide energy to optically induced carriers to transition the carriers from an intermediate band energy level to the valence band.

For example, incident light may comprise photons having energies less than the silicon bandgap, and which would otherwise not be absorbed by the photo-sensitive silicon substrate, may be absorbed by the plurality of dopant particles 106 and induce carriers, e.g., optically induced electron-hole pairs, for which the holes are formed in the valence band of the photosensitive silicon or the intermediate band energy level. Holes that are generated in the valence band (e.g., from other photons having higher energies that may be present in the incident light, e.g., UV, visible, or SWIR light having wavelengths less than or equal to 1100 nm) may diffuse into the junction and may be swept out of the intermediate band layer 104 and into photodiode 108. Holes generated in the intermediate band layer 104 (e.g., from photons corresponding to wavelengths greater than 1100 nm) that diffuse into the junction may also be swept out of the intermediate band layer 104 and into photodiode 108 while gaining energy from the electric field at the junction and transitioning to being a hole in the valence band of the photo-sensitive silicon substrate.

In some examples, holes that are optically induced in the intermediate band layer 104, e.g., via light having wavelengths greater than 1100 nm, may have a substantially short lifetime, e.g., from about 100 nanoseconds to about 1 picosecond, before being recombined if the holes are not swept into photodiode 108. There may be little or no recombination of carriers (holes, electrons) in photodiode 108. In some examples, the lifetimes of holes optically induced in the intermediate band layer 104 may be increased by several orders of magnitude, e.g., having lifetimes from about 1 microsecond to about 10 picoseconds after being swept into a carrier collection region such as photodiode 108, or having lifetimes from about 100 nanoseconds to about 10 picoseconds, or having lifetimes from about 500 picoseconds to about 50 picoseconds, or having lifetimes of about 100 picoseconds. In some examples, carrier lifetimes may be increased to read out holes at room temperature, e.g., without cooling sensing device 100. For example, sensing device 100 may be configured to sense electromagnetic radiation comprising wavelengths greater than 1100 nm at room temperature and/or without cooling sensing device 100, e.g., by collecting minority carriers optically induced in intermediated band layer 104 by the electromagnetic radiation comprising wavelengths greater than 1100 nm.

In some examples, n-type pinning layer 112 may also include a plurality of dopant particles 106 and may effectively be a second intermediate band layer and form a second n-p junction 107, which may be substantially similar to n-p junction 105 described above. In some examples, n-type pinning layer 112 and intermediate band layer 104 may both comprise an n-type pinning layer, e.g., a layer doped with n-type “impurities,” and intermediate band layer 104 and n-type pinning layer 112 may each comprise a plurality of dopant particles 106. For example, having both layers 104 and 112 configured to be intermediate band layers via doping both layers 104 and 112 with dopant particles 106 may provide an increased density of dopant particles 112 while keeping the thickness of each layer 104 and 112 relatively thin, and may provide two n-p junction interfaces from which to sweep optically induced minority carriers into photodiodes 108.

FIG. 2 is an expanded view of a portion 160 of the cross-sectional block diagram of FIG. 1 illustrating intermediate band layer 104, plurality of dopant particles 106, and n-p junction 105 of sensing device 100. In some examples, intermediate band layer 104 may comprise a pinning implant configured to adjust, or tune, the Fermi levels of intermediate band 104. For example, intermediate band layer 104 may comprise a plurality of n-type donor particles. FIG. 3 is an expanded view of the portion 160 of the cross-sectional block diagram of FIG. 1 illustrating the intermediate band layer 104 including the plurality of dopant particles 106 and a second plurality of dopant particles 206, e.g., pinning implant particles 206. Pinning implant particles 206 may comprise arsenic (e.g., for a hole sensor) or boron (e.g., for electron sensors). Pinning implant particles 206 may be configured to adjust a Fermi level of intermediate band layer 104. In some examples, pinning implant particles 206 are configured to form a potential voltage gradient to facilitate carrier excitation conversion from intermediate band layer 106 to the valence band or conduction band of the photo-sensitive silicon substrate. In some examples, pinning implant particles 206 are configured to reduce a dark current of sensors 101 and 103. In some examples, pinning implant particles 206 may be configured to increase an absorption of electromagnetic radiation having wavelengths greater than 1100 nm, e.g., by the plurality of dopant particles 106. For examples, the absorption of photons having energies less than the band gap energy of the photo-sensitive silicon substrate (e.g., photons corresponding to wavelengths greater than 1100 nm) by a plurality of sulfur dopant particles may be increased when intermediate band layer 104 is “electron rich” via doping with n-type dopants such as arsenic, as opposed to a lack of electrons. In some examples, n-type pinning layer 112 may also include pinning implant particles 206.

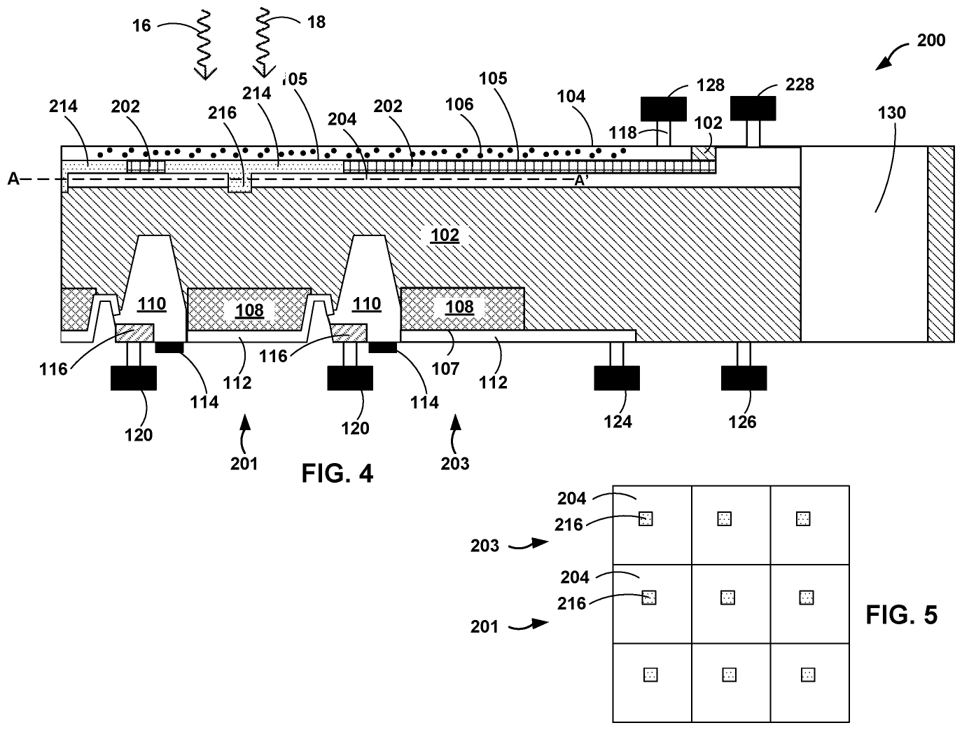

FIG. 4 is a cross-sectional block diagram illustrating another example sensing device 200, in accordance with the techniques of the disclosure. Sensing device 200 may be substantially similar to sensing device 100 described above, except that sensing device 200 includes n-well 204. In the examples shown, sensing device 200 includes sensors 201, 203 (e.g., pixels 201, 203). In some examples, sensing device 200 comprises a sensor or pixel array of sensors substantially similar to sensors 201, 203. Sensors 201, 203 may be substantially similar to sensors 101, 103 described above, except with the addition of n-well 204, and in some examples, sensors 101, 103 may include the additional features, elements, and/or functionalities described herein with reference to FIG. 4 and FIG. 5.

N-well 204 may be formed “underneath” intermediate band layer 104, e.g., N-well 204 may be implanted by doping with n-type silicon slightly deeper into p-type silicon 102 than intermediate band layer 104. N-well 204 may be configured to control the electric field near the n-p junction 105. In some examples, n-well 204 may be configured to improve and/or increase the number of optically induced carriers that transition from an intermediate band energy level to the valence band, e.g., by controlling the electric field in the region of n-p junction 105. In the example shown, n-well 204 is electrically connected to n-well contact 228, which may be located at or along one or more edges, boundaries, or the periphery of sensing device 200. In some examples, a bias voltage, e.g., a positive bias for sensing device 200 constructed as a hole sensor, may be applied to n-well 204 via contact 228. In some examples, n-well 204 may be substantially similar to intermediate band layer 104 described above except n-well 204 does not include the plurality of dopant particles 106 and is located underneath (e.g., further from the surface of sensing device 200) intermediate layer 104. In other examples, n-well 204 may be substantially similar to intermediate band layer 104 described above and also include one or both of the plurality of dopant particles 106 and the pinning implant particles 206. In some examples, intermediate band layer 104 and n-well 204 may have the same n-type doping or different n-type doping, and may have the same thickness (e.g., in the depth direction) or a different thickness.

In some examples, sensing device 200 may include p-type layer 214 disposed between intermediate band layer 104 and n-well 204. P-type layer 202 may be a relatively thin layer of p-type silicon including an additional p-type implant, e.g., an increased p-type doping relative to p-type silicon 102. Sensing device 200 may also include a touch up p-type layer 202 comprising a net p-type doping that is less than p-type layer 214 and configured to contain optically induced carriers within each pixel, e.g., within each of sensors 201 and 203. For example, touch up p-type layer 202 may be disposed at substantially the same depth as p-type layer 214 and disposed in regions between pixels, e.g., between sensos 201, 203. Touch up p-type layer 202 may be configured to improve the modulation transfer function (MTF) of sensing device 200, e.g., via containing optically induced carriers within the pixel/sensor within which they are induced for readout from that sensor/pixel.

Sensing device 200 may also include p-type drain 216. FIG. 5 is a cross-section top view of sensing device 200 as a pixel array including an plurality of sensors, the cross-section being at a depth within the sensing device 200 corresponding to n-well 204 and along the line A-A′ as shown in FIG. 4. As illustrated in FIGS. 4 and 5, each sensor of sensing device 200, e.g., sensor 201 and 203, includes a p-type drain 216. P-type drain 216 extends through a portion of n-well 204 in a depth direction between p-type layer 214 and p-type silicon 102, e.g., a p-type via connecting p-type layer 214 and p-type silicon 102 through n-well 204. P-type drain 216 may be configured to provide a path for optically induced carriers collected in p-type layer 204 to move and/or be swept into photodiode 108, e.g., to escape p-type layer 204 between the n-type intermediate band layer 104 and n-well 204.

In some examples, in operation, sensing device 200 is configured to have a positive backside bias (negative for sensing device 200 constructed as an electron sensor) applied to intermediate band layer 104 via backside contact 128 that is greater than a positive bias applied to n-well 204 via contact 228, e.g., several volts greater. In some examples, sensing device 200 is configured to have a positive bias applied to n-well 204 via contact 228 that is greater than a positive bias applied to n-type pinning layer 112, e.g., several volts greater.

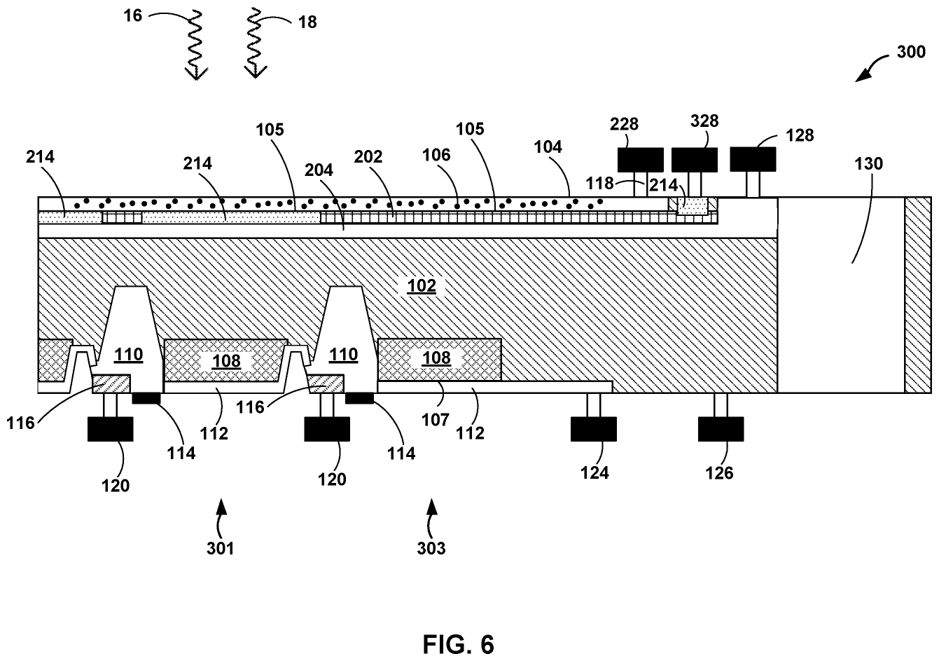

FIG. 6 is a cross-sectional block diagram illustrating example sensing device 300, in accordance with the techniques of the disclosure. Sensing device 300 may be substantially similar to sensing device 200 described above, except that sensing device 300 may or may not include p-type drain 216 and p-type layer 214 is electrically connected to p-well contact 328. In the example shown, sensing device 300 includes sensors 301, 303 (e.g., pixels 301, 303). In some examples, sensing device 300 comprises a sensor or pixel array of sensors substantially similar to sensors 301, 303. Sensors 301, 303 may be substantially similar to sensors 201, 203 described above, except that sensors 301, 303 may or may not include p-type drain 216 and p-type layer 214 is electrically connected to p-well contact 328, and in some examples, sensors 301, 303 may include the additional features, elements, and/or functionalities described herein with reference to FIG. 6.

P-type layer 214 may be configured to be a p-well, and may be configured to be biased (e.g., a positive bias for sensing device 300 as a hole sensor) via p-well contact 328. In some examples, p-well contact may be located at an edge, boundary, and/or a periphery of sensing device 300. Sensing device 300 is configured to provide additional pulling electrostatic potential configured to convert optically induced carriers in the intermediate band layer 104 to carriers in the valence band (or conduction band, for sensing device 300 constructed as an electron sensor), relative to sensing devices 100 and/or 200.

In some examples, n-p junction 105 may be more abrupt, e.g., one or both of the n-type doping of intermediate band layer 104 and the p-type doping of p-type layer 214 may be greater than sensing devices 100 and/or 200, e.g., the net p-n doping level may be greater. In some examples, charge carriers may be stored in p-type layer 214, e.g., if a positive voltage bias applied to p-type layer 214 via p-well contact 328 is less than a positive voltage bias applied to n-well 204 via n-well contact 228, which in turn is less than a positive voltage bias applied to intermediate band layer 104 via backside contact 128.

In some examples, sensing device 300 is configured to have a bias applied to n-well 204 to be pulsed, alternated, or otherwise changed, e.g., to sweep and/or transfer optically induced carriers in the intermediate band layer 104 to photodiode 108. For example, n-well 204 may be configured to by pulsed with a negative voltage bias to transfer charge from p-type layer 214 to photodiode 108.

In some examples, sensing device 300 is configured to have a positive voltage bias applied to intermediate band layer 104, via contact 128, that is larger than a positive voltage bias applied to n-well layer 204, via contact 228, e.g., larger by several volts. Sensing device is configured to control an electric field substantially near n-p junction 105 (e.g., the depletion edge of intermediate band layer 104), e.g., via the voltages applied to contacts 128, 228, and/or 328. In some examples, controlling the electric field substantially near n-p junction 105 increases the rate at which optically induced carriers in the intermediate band layer 104 are converted to carriers in the valence band (or conduction band for sensing device 300 constructed as an electron sensor). For example, optically induced carriers in the intermediate band layer 104 may be stored in p-type layer 214, e.g., which may function as a photodiode and have an increased carrier lifetime and reduced recombination rate relative to intermediate band layer 104. The voltage bias applied to n-well 204 may be pulsed to block or assist in transferring and/or draining the optically induced carriers to photodiode 108. In some examples, n-well 204 may be partially depleted, and may not be fully depleted.

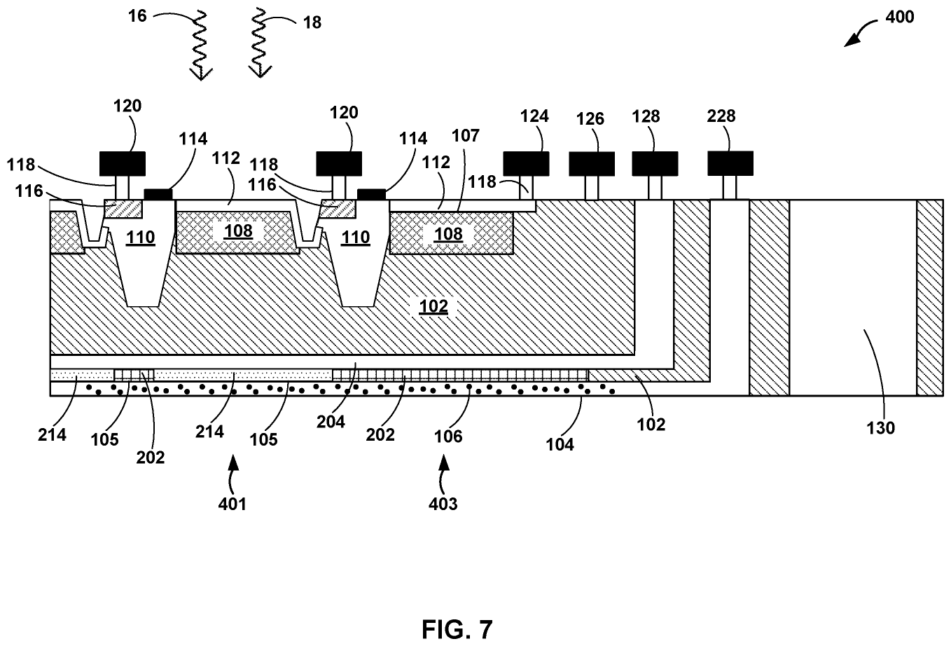

FIG. 7 is a cross-sectional block diagram illustrating example sensing device 400, in accordance with the techniques of the disclosure. Sensing device 400 may be substantially similar to sensing device 300 described above, except that sensing device 400 is constructed as a front side illuminated device. For example, light 16 and light 18 is incident on a front side surface of sensing device 400 substantially near photodiodes 108 and/or n-type pinning layer 112. In the example shown, intermediate band layer 104 is buried beneath, e.g., in the depth direction relative to a surface on which light 16 and/or 18 is incident, photodiodes 108 and readout transistors, e.g., p-channel transistors 116, gate contacts 114, and n-wells 110. In other words, sensing device 400 is configured with intermediate band layer 104 on the backside of sensing device 400 and on an opposite side of the readout transistors and photodiodes 108 relative to a surface on which light 16 and light 18 is incident. In some examples, although not shown, sensing device 400 may also include a contact electrically connected to p-type layer 214, e.g., substantially similar to contact 328 shown in FIG. 6, configured to enable a bias voltage to be applied to p-type layer 214 vi the contact.

In the example shown, sensing device 400 includes sensors 401, 403 (e.g., pixels 401, 403). In some examples, sensing device 400 comprises a sensor or pixel array of sensors substantially similar to sensors 401, 403. Sensors 401, 403 may be substantially similar to sensors 301, 303 described above, except that sensors 401, 403 may be constructed as front side illuminated sensors, and in some examples, sensors 401, 403 may include the additional features, elements, and/or functionalities described herein with reference to FIG. 7.

In the example shown, carriers generated by absorption of light 18 (e.g., within the second wavelength range including UV/VIS/SWIR light less than or equal to 1100 nm) may be collected in front side photodiodes 108. Carriers generated by absorption of light 16 (e.g., within the first wavelength range including IR light greater than 1100 nm) may be captured within intermediate band layer 104 and swept to, collected, and/or transitioned to photodiodes 108, e.g., via transitioning the carriers from the intermediate band energy level to the valence band. In some examples, n-well 204 is shuttered (e.g., “opened” or “closed” to allowing optically induced carriers within intermediate band layer 104 via application of a positive or negative voltage bias to n-well 204) to transfer optically induced carriers from one or both of intermediate band layer 104 and p-type layer 214 to the photodiodes 108.

In some examples, sensing device 400 is configured to read out a first signal generated by absorption, detection, and/or sensing light 16 separately, e.g., at a different time, from reading out a second signal generated by absorption, detection, and/or sensing light 18. For example, sensing device 400 may configured to read out signal from photodiode 108 generated in response to absorbing light 18 having a second range of wavelengths that is less than or equal to 1100 nm at a first time, and subsequently reading out a signal from photodiode 108 generated in response to absorbing light 16 (e.g., and collecting optically induced carriers converted from the intermediate band energy level to the valence band and collected in photodiode 108) having a second range of wavelengths that greater than 1100 nm at a second time. In some examples, sensing device 400 may be configured to separately readout signals generated by absorption, detection, and/or sensing light 16 and light 18 via shuttering n-well 204.

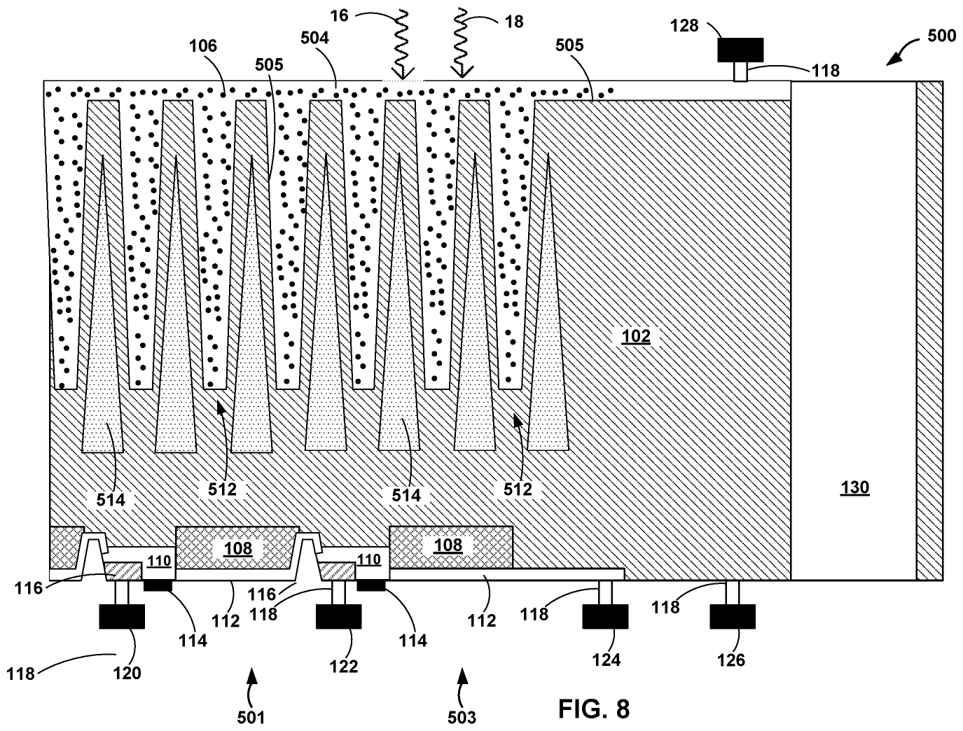

FIG. 8 is a cross-sectional block diagram illustrating another example sensing device 500, in accordance with the techniques of the disclosure. Sensing device 500 may be substantially similar to sensing device 100 described above, except that sensing device 500 includes intermediate band layer 504, n-p junction 505, and depth structures 514. Intermediate band layer 504 includes one or more depth structures 512. N-p junction 505 may be substantially similar to n-p junction 105 described above, except n-p junction 505 may follow a contour of depth structures 512 and at least a portion of n-p junction 505 may extend in the depth direction towards photodiodes 108.

In the example shown, sensing device 500 includes sensors 501, 503 (e.g., pixels 501, 503). In some examples, sensing device 500 comprises a sensor or pixel array of sensors substantially similar to sensors 501, 503. Sensors 501, 503 may be substantially similar to sensors 101, 103 described above, except with the addition of depth structures 512, 514, and in some examples, the additional features, elements, and/or functionalities described herein with reference to FIG. 8.

Depth structures 512 may comprise at least a portion of intermediate band layer 504 that extends in a depth direction towards photodiodes 108, e.g., at a plurality of positions about the area of sensing device 500. Depth structures 512 may include the plurality of dopant particles 106 dispersed throughout depth structures 512. Depth structures 512 may also include a plurality of pinning implant particles 206 (not shown). In some examples, depth structures 504 may extend in the depth direction for greater 5% of the depth (e.g., thickness) of sensors 501, 503 between the front and back sides of sensing device 500, or for greater than 10% of the depth of sensors 501, 503, or for greater than 50% of the depth of sensors 501, 503, or for greater than 90% of the depth of sensors 501, 503.

Depth structures 512 may comprise any suitable shape. In the example shown, depth structures 512 comprise a trapezoidal cross-sectional shape, but in other examples depth structure 512 may have a cylindrical shape, spherical shape, rectangular shape, triangular shape, a sinusoidal shape, or any suitable shape. In some examples, depth structures 512 form a periodic pattern within the area and/or volume of sensing device 500, such as linear pattern of ribs or channels, a checkerboard pattern, or any suitable pattern. In the example shown, depth structures 512 are spaced apart, but in other examples depth structures may not be spaced, e.g., may be directly adjacent without a space or overlapping.

Intermediate band layer 504 is configured to increase an optical density of sensing device 500, e.g., via depth structures 512, for at least incident electromagnetic radiation comprising the first range of wavelengths greater than 1100 nm, e.g., light 18. For example, depth structures 512 are configured to increase an optical path length through which light 18 propagates within sensing device 500 and increasing the absorption and optical density of sensing device 500 to light 18.

Depth structures 514 may comprise any suitable shape. In the example shown, depth structures 514 comprise a triangular cross-sectional shape, but in other examples depth structure 512 may have a cylindrical shape, spherical shape, rectangular shape, trapezoidal shape, a sinusoidal shape, or any suitable shape. In some examples, depth structures 514 form a periodic pattern which may be complementary to depth structures 512 within the area and/or volume of sensing device 500, such as linear pattern of ribs or channels, a checkerboard pattern, or any suitable pattern. In some examples depth structures 514 may not be patterned and may be distributed substantially randomly or according to a predetermined set of positions. In the example shown, depth structures 514 are spaced apart, but in other examples depth structures may not be spaced, e.g., may be directly adjacent without a space or overlapping. Depth structures 514 may comprise p-type doped silicon similar to p-type layer 214 described above. Depth structures 514 may be configured to steer, guide, and/or otherwise facilitate sweeping of optically induced carriers generated in intermediate band layer 504 to photodiodes 108. In some examples, depth structures 514 may be configured to contain optically induced carriers within each pixel, e.g., within each of sensors 501 and 503. For example, depth structures 514 may be disposed so as to guide an optically induced carrier generated within intermediate band layer 504 to a photodiode 108 that is closest to a position at which a photon 18 is absorbed to generate the optically induced carrier. In other words, depth structures 514 may be configured to improve the MTF of sensing device 500, e.g., via containing optically induced carriers within the pixel/sensor within which they are induced for readout from that sensor/pixel.

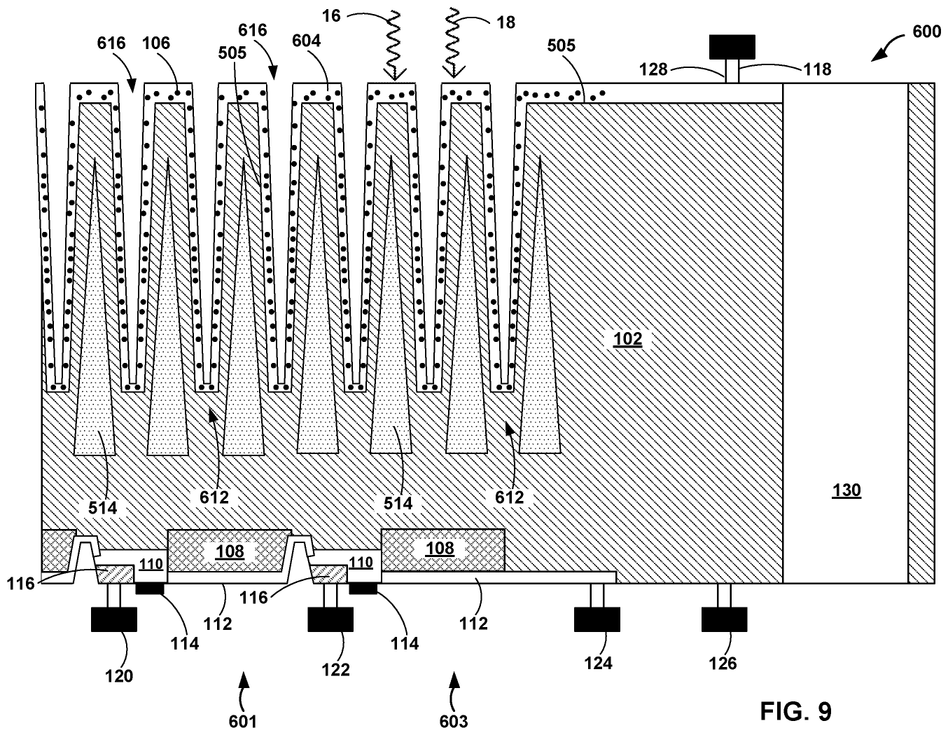

FIG. 9 is a cross-sectional block diagram illustrating another example sensing device 600, in accordance with the techniques of the disclosure. Sensing device 600 may be substantially similar to sensing device 500 described above, except that sensing device 600 includes intermediate band layer 604. Intermediate band layer 604 includes one or more depth structures 612. Intermediate band layer 604 and depth structures 612 may be substantially similar to intermediate band layer 504 and depth structures 512 described above, except that depth structures 612 are formed with recesses 616 (e.g., trenches 616). For example, intermediate band layer 604 may be a layer with a substantially uniform thickness that follows the contours of the shapes of depth structures 612. In some examples, the thickness of intermediate layer 604 may vary depending on position relative to depth structures 612, e.g., thicker on surfaces substantially coplanar with back side surface of sensing device 600 and thinner on the side wall surfaces of depth structures 612.

In the example shown, sensing device 600 includes sensors 601, 603 (e.g., pixels 601, 603). In some examples, sensing device 600 comprises a sensor or pixel array of sensors substantially similar to sensors 601, 603. Sensors 601, 603 may be substantially similar to sensors 501, 503 described above, except with that sensors 601, 603 include depth structures 612 rather than depth structures 512, and in some examples, the additional features, elements, and/or functionalities described herein with reference to FIG. 9.

In some examples, recesses 616 may be vacuum filled, air filled, or filled with a material such as silica dioxide or any suitable dielectric material. In some examples, depth structures 612 are configured to reduce reflections from the front side surface of sensing device 600, e.g., Fresnel reflections. For example, recesses 616 comprise a material having an index of refraction for light 16 and/or 18 that is less than the materials of sensing device 600 (e.g., less than intermediate band layer 604, silicon, and the like) and may be configured to be “light traps” for incident light 16 and/or 18. For example, depth structures 612 may be configured to provide an incident optical path having numerous reflections before light 16 and/or 18 reflects out of recesses 616 and away from sensing device 600, thereby increasing the number of interfaces at which light 16 and/or 18 may transmit rather than reflect and increasing the transmission of light 16 and/or 18 into sensing device 600 relative to a sensing device having a planar front side surface, such as sensing device 500 of FIG. 8. In some examples, depth structures 612 are configured to decrease the net amount of light 16 and/or 18 reflected from sensing device 600 (and increase the transmission of light 16 and/or 18 into sensing device 600) at substantially any incidence angle of light 16 and/or 18. In some examples, depth structures 612 are configured to provide a graded index and/or gradient index (GRIN) surface of sensing device 600. For example, depth structures 612 may be configured to have an index of refraction that is between that of air and intermediate band layer 604. In some examples, depth structures 612 may be configured to have an index of refraction that varies as a function of depth, e.g., increasing in depth. In some examples, depth structures 612 may comprise subwavelength structures, e.g., having thicknesses in directions coplanar with the back side and/or front side surfaces of sensing device 600 that are substantially the same as or less than the wavelength so light 16 and/or 18, e.g., “moth eye” type subwavelength structures.

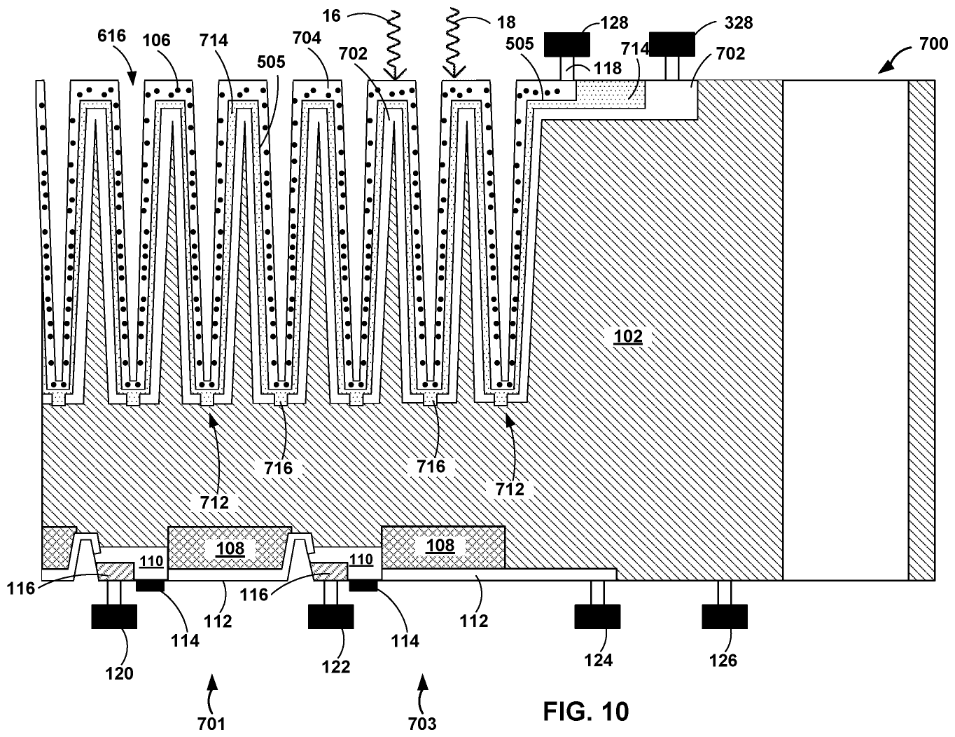

FIG. 10 is a cross-sectional block diagram illustrating another example sensing device 700, in accordance with the techniques of the disclosure. Sensing device 700 may be substantially similar to sensing devices 600 described above, except that sensing device 700 intermediate band layer 704 and n-p junction 505, and may not include depth structures 614. Intermediate band layer 704 includes one or more depth structures 712. Depth structures 712 may be substantially similar to depth structures 612 described above, except that depth structures 712 may include n-well 704 and may optically include p-type layer 714, touch up p-type layer 702, and p-type drains 716. N-well 704, p-type layer 714, touch up p-type layer 702, and p-type drains 716 may be substantially similar to n-well 204, p-type layer 214, touch up p-type layer 202, and p-type drains 216 of FIGS. 4 and 5 described above, except that n-well 704, p-type layer 714, touch up p-type layer 702, and p-type drains 716 may be layers and/or structures that follow the a contour of one or more of depth structures 712. In some examples, sensing device 700 includes a contact electrically connected to p-type layer 714, e.g., substantially similar to contact 328 and p-type layer 214 described above. In some examples, n-well 704, p-type layer 714, touch up p-type layer 702, and p-type drains 716 are configured to provide control of an electric field near n-p junction 505 and provide a path for optically induced carriers to be swept into photodiodes 108 and pixel-wise containment of optically induced carriers to be swept into photodiodes substantially near the position at which a photon 16 and/or 18 is absorbed to generate the carrier.

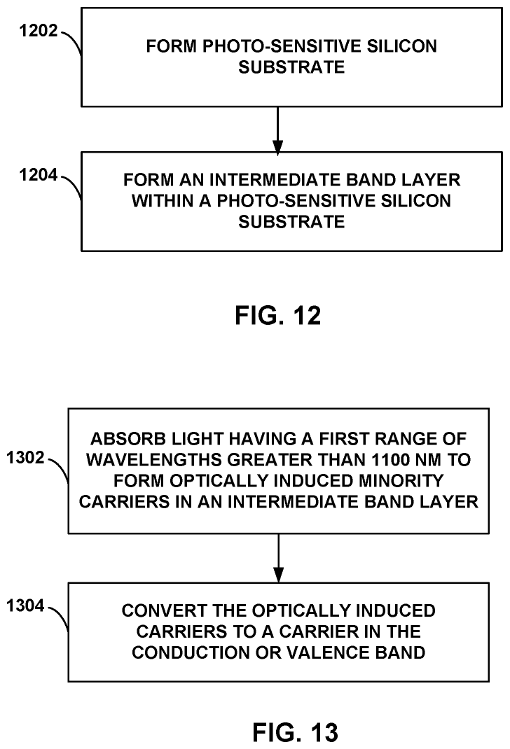

FIG. 12 is a flow diagram of an example method of forming a sensor and/or sensing device, in accordance with the techniques of the disclosure. The method is described with reference to sensing device 100 and sensors 101, 103 of FIG. 1, however, the techniques of FIG. 12 may be utilized to make different sensors, such as sensing devices 200-700 and/or sensors 201-701 and 203-703.

A manufacturer may form a photo-sensitive silicon substrate (1202). For example, the manufacturer may form n-type and/or p-type photodiodes 108 in an n-type and/or p-type silicon substrate and/or wafer. In some examples, the manufacturer may form the photo-sensitive silicon substrate as a front side illuminated or a back side illuminated sensor configured to sense light 16 having the second range of wavelengths less than or equal to 1100 nm.

The manufacturer may form an intermediate band layer 104 on a surface of a photo-sensitive silicon substrate (1204). For example, the manufacturer may implant, mix, laser anneal, or other dope a plurality of dopant particles 106 into a portion of a volume of a silicon substrate, such as p-type silicon 102. The volume may be a substantially thin and/or shallow volume, such as illustrated in FIG. 1, or may include one or more depth structures, such as depth structures 512-712 of FIGS. 8-10. In some examples, the manufacturer may additionally dope the volume comprising intermediate band layer 104 with n-type dopants (e.g., for a hole sensor) or p-type dopants (e.g., for an electron sensor). The manufacturer may sparsely or densely disperse the plurality of dopant particles 106 substantially uniformly within the volume. The intermediate band layer 104 may be configured to absorb a portion of incident electromagnetic radiation 18 comprising a first range of wavelengths greater than 1100 nm and form optically induced minority carriers. The intermediate band layer may be formed in the photo-sensitive silicon substrate adjacent to n-p junction 105, and n-p junction may be configured to convert a carrier optically induced in intermediate band layer 104 to a carrier in the valence band or the conduction band. In some examples, the manufacturer may doping the intermediate band layer with a plurality of pinning implant particles 206 configured to adjust a Fermi level of the intermediate band layer. In some examples, the manufacturer may form a plurality of depth structures 512, 612, and/or 712 configured increase an optical density of the sensor for the incident electromagnetic radiation 18 comprising the first range of wavelengths greater than 1100 nm.

FIG. 13 is a flow diagram of an example method of detecting electromagnetic radiation, in accordance with the techniques of the disclosure. The method is described with reference to sensing device 100 and sensors 101, 103 of FIG. 1, however, the techniques of FIG. 12 may be utilized to make different sensors, such as sensing devices 200-700 and/or sensors 201-701 and 203-703.

A sensing device 100 may absorb light 18 having a first range of wavelengths greater than 1100 nm to form optically induced minority carriers in intermediate band layer 104 (1302). For example, a silicon sensor comprising intermediate band layer 104 comprising a plurality of dopant particles 106 may absorb incident electromagnetic radiation 18 comprising a first range of wavelengths greater than 1100 nm which forms optically induced minority carriers in intermediate band layer 104.

The sensor 100 may then convert the optically induced carriers to a carrier in the valence or conduction band (1304). For example, the optically induced carriers may be swept out of intermediate band layer 104 to a photodiode 108, and the optically induced carriers may be converted from an intermediate band energy level to the valence or conduction band via an increase in energy of the carrier by an electric field at or near n-p junction 105. In some examples, the electric field may be actively controlled via bias voltages, and/or the electric field may be a junction potential of n-p junction 105 or 705.

The foregoing system and embodiments thereof have been provided in sufficient detail, but it may be not the intention of the applicant(s) for the disclosed system and embodiments provided herein to be limiting. Additional adaptations and/or modifications are possible, and, in broader aspects, these adaptations and/or modifications are also encompassed. Accordingly, departures may be made from the foregoing system and embodiments without departing from the spirit of the system.

1. A sensor, comprising:
an intermediate band layer comprising a plurality of dopant particles, wherein the intermediate band layer is configured to absorb a portion of incident electromagnetic radiation comprising a first range of wavelengths greater than 1100 nm and form optically induced minority carriers; and
a photo-sensitive silicon substrate configured to detect the electromagnetic radiation comprising a second range of wavelengths less than or equal to 1100 nm.

2. The sensor of claim 1, further comprising an n-p junction, wherein the intermediate band layer is formed in the photo-sensitive silicon substrate adjacent to the n-p junction.

3. The sensor of claim 2, wherein the n-p junction is configured to convert an optically induced carrier in the intermediate band layer to a carrier in the conduction band or the valence band.

4. The sensor of claim 1, wherein the intermediate band layer comprises an intermediate energy band level configured to collect minority carriers, wherein a first energy gap between the intermediate energy band level and the conduction band or the valence band of the photo-sensitive silicon substrate is less than a second energy gap between the conduction band and the valence band of the photo-sensitive silicon substrate.

5. The sensor of claim 1, further comprising:
a carrier collection region comprising a carrier lifetime that is greater than a carrier lifetime of the intermediate band layer.

6. The sensor of claim 1, wherein the plurality of dopant particles comprises at least one of a chalcogen, sulfur, selenium, tellurium, titanium, germanium, hydrogen, and silicon.

7. The sensor of claim 1, further comprising a plurality of pinning implant particles configured to adjust a Fermi level of the intermediate band layer.

8. The sensor of claim 7, wherein the plurality of dopant particles are a first plurality of dopant particles, wherein the plurality of pinning implant particles comprises a second plurality of dopant particles different from the first plurality of particles, wherein the second plurality of dopant particles is configured to form a potential voltage gradient to facilitate carrier excitation conversion from the intermediate band layer to the valence band or conduction band.

9. The sensor of claim 8, wherein the second plurality of dopant particles is configured to reduce a dark current of the sensor.

10. The sensor of claim 9, wherein the second plurality of dopant particles comprises arsenic or boron.

11. The sensor of claim 2, wherein the intermediate band layer is electrically connected to an electrical contact and is configured to form an electric field substantially near the n-p junction upon application of a voltage to the contact, the electric field being sufficient to cause a minority carrier within the intermediate band layer to transition to the valence band or the conduction band.

12. The sensor of claim 11, further comprising an n-well or a p-well electrically connected to an electrical contact and configured to control the electric field to increase conversion of optically induced carriers in the intermediate band layer to carriers in the conduction band or the valence band.

13. The sensor of claim 1, wherein the intermediate band comprises a plurality of depth structures configured to increase an optical density of the sensor for the incident electromagnetic radiation comprising the first range of wavelengths greater than 1100 nm.

14. The sensor of claim 13, wherein the plurality of depth structures comprises the intermediate band layer extending into the silicon substrate in the depth direction at a plurality of positions about the area of the sensor.

15. The sensor of claim 14, wherein the plurality of depth structures comprises a plurality of recesses extending from the surface of the sensor into the depth of the silicon substrate at a plurality of positions about the area of the sensor.

16. A method of forming a sensor, the method comprising:
forming an intermediate band layer comprising a plurality of dopant particles on a surface of a photo-sensitive silicon substrate,
wherein the intermediate band layer is configured to absorb a portion of incident electromagnetic radiation comprising a first range of wavelengths greater than 1100 nm and form optically induced minority carriers.

17. The method of claim 16, wherein the intermediate band layer is formed in the photo-sensitive silicon substrate adjacent to an n-p junction, wherein the n-p junction is configured to convert a carrier optically induced in the intermediate band layer to a carrier in the valence band or the conduction band.

18. The method of claim 16, further comprising doping the intermediate band layer with a plurality of pinning implant particles configured to adjust a Fermi level of the intermediate band layer.

19. The method of claim 16, wherein the plurality of dopant particles comprises at least one of a chalcogen, titanium, germanium, hydrogen, or silicon.

20. The method of claim 16, further comprising forming a plurality of depth structures configured increase an optical density of the sensor for the incident electromagnetic radiation comprising the first range of wavelengths greater than 1100 nm.

21. A method of detecting electromagnetic radiation, the method comprising:
absorbing, by a silicon sensor comprising an intermediate band layer comprising a plurality of dopant particles, incident electromagnetic radiation comprising a first range of wavelengths greater than 1100 nm, wherein absorbing the incident electromagnetic radiation comprising a first range of wavelengths greater than 1100 nm forms optically induced minority carriers; and
converting, via an n-p junction of the photo-sensitive silicon substrate, a minority carrier optically induced in the intermediate band layer to a carrier in a conduction band or a valence band of the silicon sensor.
